(19) United States
(12) Patent Application Publication
(10) Pub. No.: US 2012/0216397 A1
(43) Pub. Date: Aug. 30, 2012

(54) METHOD FOR BUILDING SIDE ILLUMINATION FOR A WHEEL

(76) Inventor: Miles Foster, San Francisco, CA (US)

(21) Appl. No.: 13/401,845

(22) Filed: Feb. 22, 2012

Related U.S. Application Data
(60) Provisional application No. 61/446,159, filed on Feb. 24, 2011.

(51) Int. Cl. H05K 13/04; B23B 35/00; B23P 17/00

(52) U.S. Cl. 29/825; 29/428; 29/407.01; 408/1 R

(57) ABSTRACT

This is directed to systems, processes, machines, and other means that allow side illumination for a wheel. The invention can enable a bicycle user to control the amount of light produced by lights installed into a wheel in an efficient manner.

### CROSS REFERENCE TO RELATED APPLICATIONS

This application claims priority to provisional patent application No. 61/446,159 filed on Feb. 24, 2011.

### STATEMENT REGARDING FEDERALLY SPONSORED RESEARCH OR DEVELOPMENT

Not Applicable

### THE NAMES OF PARTIES TO A JOINT RESEARCH AGREEMENT

Not Applicable

### INCORPORATION BY REFERENCE OF MATERIAL SUBMITTED ON A COMPACT DISC

Not Applicable

### FIELD OF THE INVENTION

This invention relates to illuminating bicycle tires.

### BACKGROUND OF THE INVENTION

Bicycle wheels have been illuminated in a number of ways over the years, with devices such as lamps (See Betts, U.S. Pat. No. 540,605) and reflectors (See Rider, U.S. Pat. No. 2,293,849). More recently, it has become popular to use light emitting diodes attached to the wheels or spokes of the bicycle with an adhesive as shown in the background art below. However, there is presently no disclosed method for drilling holes into the wheel and inserting LED lights into the hole, perhaps because of concerns for wheel stability. The disclosed invention solves those problems.

### BACKGROUND ART

The Moore U.S. Pat. App. No. 2010/172145 teaches a mount for mounting a light to a bicycle where. It does not teach drilling holes into the wheel, nor does it explain how to determine the positions of the holes.

The Washington U.S. Pat. No. 7,213,953 teaches an illumination device designed to be attached to a wheel with adhesive material. It teaches away from the drilling technique used in the current application by emphasizing a different and inadequate method of attachment.

The Reim U.S. Pat. No. 7,079,042 teaches method for placing an illuminated display on a wheel. Like the Washington patent, it teaches away from drilling into the wheel by teaching an adhesive layer connecting the LED to the wheel.

### BRIEF SUMMARY OF THE INVENTION

Methods, systems, and other means are provided for a method for building side illumination for a wheel. In accordance with some embodiments the method for building side illumination for a wheel involves a user first conducts a feasibility study to collect data about stress points of the wheel. Second a user determines locations on the wheel for lighting devices based on analysis of the data collected. Next, a user forms a plurality of cavities in the wheel to accommodate the lighting devices. Finally, a user installs the lighting devices into the plurality of cavities. Additionally, reinforcement can be provided into the cavities as necessary. The cavities can be made by a variety of techniques including active drilling, horizontal drilling, cross drilling, vertical drilling, longitudinal drilling and a variety of other methods. These cavities can be threaded to hold the light better into the wheel.

### BRIEF DESCRIPTION OF THE SEVERAL VIEWS OF THE DRAWINGS

Having thus described the invention in general terms, reference will now be made to the accompanying drawings, which are not necessarily drawn to scale, and wherein:

FIG. 1 is a flowchart illustrating a method for building side illumination for a wheel according to an exemplary embodiment of the present invention.

FIG. 2 is a perspective view of a side illumination for a bicycle wheel according to another exemplary embodiment of the present invention.

FIG. 3: is a detailed perspective view of the invention.

FIG. 4: is a section view of taken along line 4-4 in FIG. 3.

FIG. 5: is an exploded perspective view of the invention.

### DETAILED DESCRIPTION OF THE INVENTION

Embodiments of the present invention overcome many of the obstacles associated with illuminating bicycle wheels, and now will be described more fully hereinafter with reference to the accompanying drawings that show some, but not all embodiments of the claimed inventions. Indeed, the invention may be embodied in many different forms and should not be construed as limited to the embodiments set forth herein. Rather, these embodiments are provided so that this disclosure will satisfy applicable legal requirements. Like numbers refer to like elements throughout.

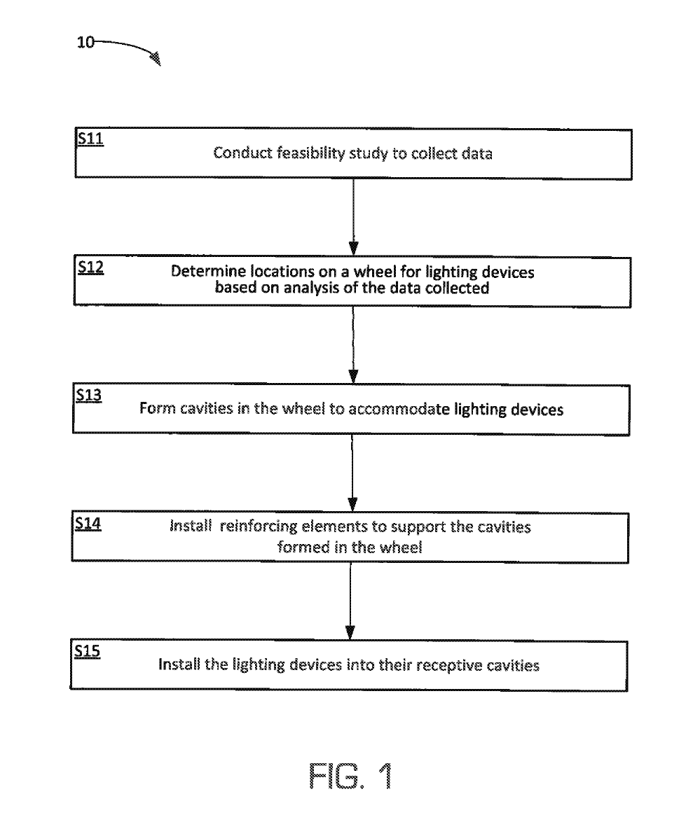

FIG. 1 shows method 10 for building side illumination for a bicycle wheel. Method 10 begins with Step S11 which comprises conducting a stress concentration analysis. Methods for stress testing wheels are well known. See Fischer, U.S. Pat. No. 6,116,084 which teaches a device for testing a wheel. When wheels are stress tested they provide data for determining the mechanical properties of those wheels. Once those properties are known traditional techniques for determining stress concentration and how those stresses are affected by inserting cavities are well known as well. See Pilkey, et al., Peterson's Stress Concentration Factors (2008). The present invention, in Step S11, uses these well-known methods and others to determine the effect of making cavities in a wheel in different locations. Notably, wheels already have cavities based on spokes that are inside them, and the present invention merely determines where additional cavities would have the least effect on predictable loading in a wheel. In particular, the analysis may include performing an appropriate series of tests to collect sufficient data about displacement, reaction force, stress, and strain energy points of the bicycle wheel. The tests may be performed by field testing, software simulation or both depending on user preference.

Step S12 comprises determining locations on a wheel for lighting devices based on analysis of the data collected in Step S11. Analyzing the collected data can provide information about the safest points where the bicycle wheel may be penetrated to create a plurality of cavities to receive the lighting equipment. The location of a cavity can depend upon the structural integrity of each individual wheel design.

Step S13 may include forming the plurality of cavities in the wheel to accommodate lighting devices. Cavity forming may be done by removing material from the wheel or the cavity may be designed into the mold of the wheel prior to casting. For instance, this can be done by active drilling, horizontal drilling, cross drilling, vertical drilling, longitudinal drilling or a variety of other methods.

After the plurality of cavities have been formed in Step S13 they may be reinforced in Step S14 which may include installing reinforcing elements to support the plurality of cavities formed in the wheel. The reinforcing element's material, shape, and size may vary upon the material, shape, and size of the wheel. Reinforcement is important to resolving the matter of structural integrity which has been untouched by the prior art.

Step S15 may include installing the lighting devices into their receptive cavities. As shown in FIG. 5 below, this can be done by mechanically coupling switches, LEDs and batteries.

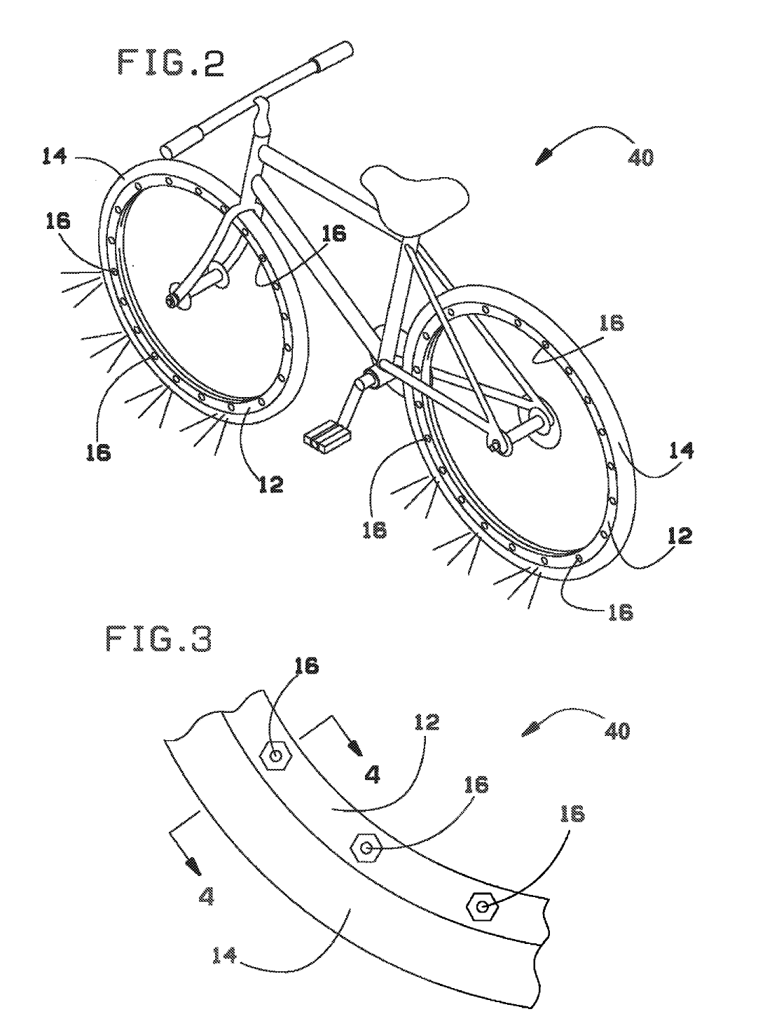

FIG. 2 shows bicycle 40 using coupled with the method shown in FIG. 1. Bicycle 40 comprises wheel 12. Wheel 12 is mechanically coupled to tire 14 as is well known in the art. Wheel 12 further comprises LED lights 16 as shown in more detail in FIG. 3.

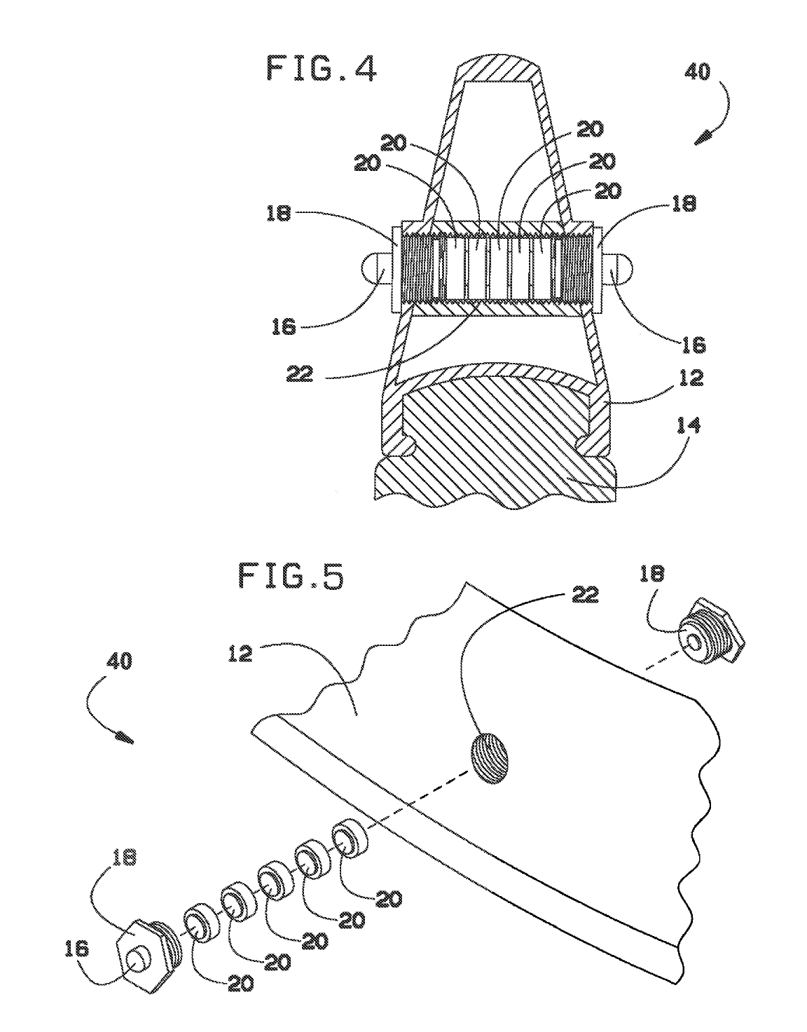

FIG. 3 shows wheel 12 in more detail. As explained above wheel 12 contains a plurality of LED lights 16 which are placed as determined in method Step S11, Step S12, Step S13 and Step S14 as explained in FIG. 1. LED lights 16 are inserted in wheel 12 as explained in method Step S15 and shown in FIG. 4 and FIG. 5 below.

FIG. 4 shows a section view of wheel 12. As indicated above wheel 12 is mechanically coupled to tire 14. Here, LED light 16 is electrically coupled to switch 18 which is further electrically coupled to batteries 20. A user can activate switch 18 to turn LED light 16 on or off depending on user preference. A user can turn as many or as few LED lights 16 on or off as one chooses. This differs from the Reim patent above that requires a complicated computer program to turn lights on and off.

FIG. 5 shows an assembly drawing of threaded cavity 22. A first LED light 16 is mechanically coupled to a first switch 18 where the first switch 18 is threaded with a first thread. The first thread can be threaded into a second thread in threaded cavity 22 completing a first mechanical couple. In order to complete the electrical couple noted in FIG. 4 above switch 18 will need to have a series of batteries 20 pressed against it. Further, a second LED light 16 is mechanically coupled to a second switch 18 where second switch 18 is threaded with a third thread. The third thread can be threaded into the second thread in threaded cavity 22 completing a second mechanical couple. As shown in FIG. 1, the technology of FIG. 5 can be used to create a plurality of threaded cavities.

That which is claimed:

1. A method for building side illumination for a wheel, comprising: forming a plurality of
cavities in the wheel to accommodate lighting devices; and installing the lighting devices into the plurality of cavities.

2. The method of claim 1 further comprising conducting a feasibility study to collect data about
stress points of the wheel;
determining locations on the wheel for the lighting devices based analysis of the data collected;
installing reinforcing elements to the wheel.

3. The method of claim 1 where the plurality of cavities are formed by active drilling.

4. The method of claim 1 where the plurality of cavities are formed by horizontal drilling.

5. The method of claim 1 where the plurality of cavities are formed by cross drilling.

6. The method of claim 1 where the plurality of cavities are foliated by vertical drilling.

7. The method of claim 1 where the plurality of cavities are formed by longitudinal drilling.

8. The method of claim 1 where the lighting devices further comprise a first LED light electrically coupled to a first switch and batteries where the batteries are further electrically coupled to a second switch which is further electrically coupled to a second LED light.

9. The method of claim 1 where the plurality of cavities further comprises a plurality of threaded cavities.
